(19) United States
(12) Patent Application Publication
(10) Pub. No.: US 2023/0102188 A1
(43) Pub. Date: Mar. 30, 2023

(54) OVERCURRENT PROTECTION CIRCUIT, SEMICONDUCTOR DEVICE, ELECTRONIC APPARATUS, AND VEHICLE

(71) Applicant: Rohm Co., Ltd., Kyoto (JP)

(72) Inventors: Toru Takuma, Kyoto (JP); Adrian JOITA, Kyoto (JP); Shuntaro TAKAHASHI, Kyoto (JP)

(21) Appl. No.: 17/902,295

(22) Filed: Sep. 2, 2022

(30) Foreign Application Priority Data
Sep. 30, 2021 (JP) 2021160968

(51) Int. Cl. H03F 1/52; H03F 3/217

(52) U.S. Cl. CPC H03F 1/523; H03F 3/2173

(57) ABSTRACT

An overcurrent protection circuit includes: a first transistor and a second transistor configured to form an amplifier input stage that receives input of a detection signal according to a monitoring target current; and a third transistor configured to form an amplifier output stage that generates a current output signal according to a difference between the detection signal and a reference signal and causes the current output signal to be negatively fed back to the amplifier input stage, wherein the monitoring target current is limited based on the current output signal output from the third transistor.

### CROSS-REFERENCE TO RELATED APPLICATION

This application is based upon and claims the benefit of priority from Japanese Patent Application No. 2021-160968, filed on Sep. 30, 2021, the entire contents of which are incorporated herein by reference.

### TECHNICAL FIELD

The present disclosure relates to an overcurrent protection circuit and a semiconductor device, an electronic apparatus, and a vehicle using the overcurrent protection circuit.

### BACKGROUND

The present discloser has proposed a number of new technologies regarding semiconductor devices, such as an in-vehicle IPD (Intelligent Power Device), etc.

Further, techniques related to an overcurrent protection circuit incorporated in a semiconductor device are disclosed in the related art.

However, with the overcurrent protection circuit in the related art, there is room for improvement in detection accuracy.

In particular, in recent years, in-vehicle ICs have been required to comply with ISO26262 (international standard for functional safety related to electricity/electronics of automobiles), and higher reliability design has also become important for in-vehicle IPD.

### SUMMARY

Some embodiments of the present disclosure provide a high-precision overcurrent protection circuit and a semiconductor device, an electronic apparatus, and a vehicle using the overcurrent protection circuit.

For example, according to an embodiment of the present disclosure, an overcurrent protection circuit includes: a first transistor and a second transistor configured to form an amplifier input stage that receives input of a detection signal according to a monitoring target current; and a third transistor configured to form an amplifier output stage that generates a current output signal according to a difference between the detection signal and a reference signal and causes the current output signal to be negatively fed back to the amplifier input stage, wherein the monitoring target current is limited based on the current output signal output from the third transistor.

Other features, elements, steps, advantages, and characteristics will be further clarified by the following embodiments by which out the present disclosure is carried out and the accompanying drawings related thereto.

### BRIEF DESCRIPTION OF DRAWINGS

FIG. 1 is a diagram showing a configuration example of an electronic apparatus including a semiconductor device.

FIG. 2 is a block circuit diagram showing an electrical structure of the semiconductor device.

FIG. 3 is a diagram showing an overcurrent protection circuit according to a first embodiment of the present disclosure.

FIG. 4 is a diagram showing an overcurrent protection circuit according to a second embodiment of the present disclosure.

FIG. 5 is an external view showing a configuration example of a vehicle.

### DETAILED DESCRIPTION

### <Electronic Apparatus>

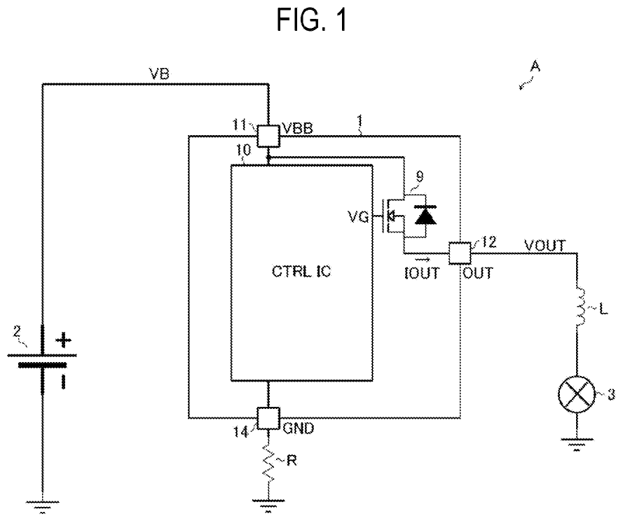

FIG. 1 is a diagram showing a configuration example of an electronic apparatus including a semiconductor device. The electronic apparatus A of this configuration example includes a semiconductor device 1, a DC power supply 2, and a load 3.

The semiconductor device 1 is a high-side switch IC (a type of IPD) that electrically connects/disconnects between the DC power supply 2 and the load 3 and integrates a power MISFET (Metal Insulator Semiconductor Field Effect Transistor) 9 and a control IC (Integrated Circuit) 10.

Further, the semiconductor device 1 includes a plurality of external electrodes configured to establish an electrical connection with the outside of the device. As shown in this figure, the semiconductor device 1 includes a drain electrode 11 (corresponding to a power supply electrode VBB), a source electrode 12 (corresponding to an output electrode OUT), and a reference voltage electrode 14 (corresponding to a ground electrode GND).

The power MISFET 9 is an example of an insulated gate type power transistor (output transistor), and functions as a high-side switch element that electrically connects/disconnects between the drain electrode 11 and the source electrode 12.

The control IC 10 includes a plurality of types of functional circuits that realize various functions. For example, the plurality of types of functional circuits include a circuit that generates a gate control signal VG that drives and controls the power MISFET 9 based on an electric signal from the outside.

The drain electrode 11 transmits a power supply voltage VB to the drain of the power MISFET 9 and various circuits of the control IC 10. The source electrode 12 is connected to the source of the power MISFET 9 and transmits an output voltage VOUT and an output current IOUT to the load 3. A signal line (for example, a wire harness) provided between the source electrode 12 and the load 3 is generally accompanied by an inductance component L (and a resistance component). An input electrode 13 transmits an input voltage (input signal IN) to drive the control IC 10. The reference voltage electrode 14 transmits a reference voltage (for example, a ground voltage) to the control IC 10. Further, a resistance component R is generally connected between the reference voltage electrode 14 and the ground end.

### <Semiconductor Device>

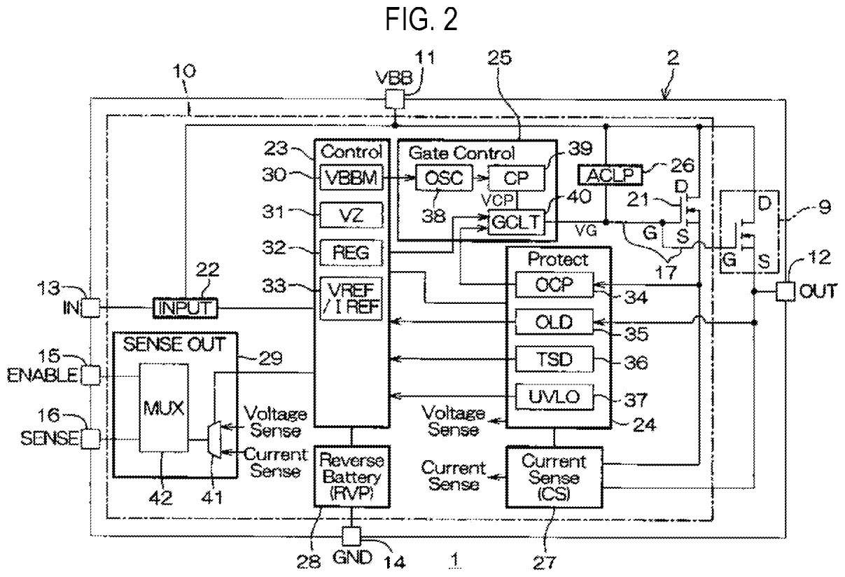

FIG. 2 is a block circuit diagram showing an electrical structure of the semiconductor device 1 shown in FIG. 1. Hereinafter, a case where the semiconductor device 1 is mounted on a vehicle will be described as an example. The semiconductor device 1 may be applied as a high-side switch configured to control electrical conduction to a light source such as a bulb lamp or an LED (Light Emitting Diode) lamp, or other types of electronic control devices when the semiconductor device 1 is mounted on the vehicle.

The semiconductor device 1 includes the drain electrode 11, the source electrode 12, the input electrode 13, the reference voltage electrode 14, an enable electrode 15, a sense electrode 16, a gate control wiring 17, the power MISFET 9, and the control IC 10.

The drain electrode 11 (the power supply electrode VBB) is connected to the DC power supply 2. The drain electrode 11 provides the power supply voltage VB to the power MISFET 9 and the control IC 10. The power supply voltage VB may be 10 V or more and 20 V or less. On the other hand, the source electrode 12 (the output electrode OUT) is connected to the load 3.

The input electrode 13 (the input electrode IN) may be connected to an MCU (Micro Controller Unit), a DC/DC converter, an LDO (Low Drop Out) regulator, or the like. The input electrode 13 provides an input voltage to the control IC 10. The input voltage may be 1 V or more and 10 V or less. The reference voltage electrode 14 is connected to a reference voltage wiring (the ground end). The reference voltage electrode 14 provides a reference voltage to the power MISFET 9 and the control IC 10.

The enable electrode 15 may be connected to the MCU. An electric signal that enables or disables a part or all of the functions of the control IC 10 is input to the enable electrode 15. The sense electrode 16 transmits an electric signal for detecting an abnormality of the control IC 10 to the outside of the device. The sense electrode 16 may be pulled up or pulled down by a resistor.

The gate of the power MISFET 9 is connected to the control IC 10 (a gate control circuit 25 to be described later) via the gate control wiring 17. The drain of the power MISFET 9 is connected to the drain electrode 11. The source of the power MISFET 9 is connected to the control IC 10 (a current detection circuit 27 to be described later) and the source electrode 12.

The control IC 10 includes a sensor MISFET 21, an input circuit 22, a current/voltage control circuit 23, a protection circuit 24, a gate control circuit 25, an active clamp circuit 26, a current detection circuit 27, a power supply reverse connection protection circuit 28, and an abnormality detection circuit 29.

The gate of the sensor MISFET 21 is connected to the gate control circuit 25. The drain of the sensor MISFET 21 is connected to the drain electrode 11. The source of the sensor MISFET 21 is connected to the current detection circuit 27.

The input circuit 22 is connected to the input electrode 13 and the current/voltage control circuit 23. The input circuit 22 may include a Schmitt trigger circuit. The input circuit 22 shapes a waveform of an electric signal applied to the input electrode 13. A signal generated by the input circuit 22 is input to the current/voltage control circuit 23.

The current/voltage control circuit 23 is connected to the protection circuit 24, the gate control circuit 25, the power supply reverse connection protection circuit 28, and the abnormality detection circuit 29. The current/voltage control circuit 23 may include a logic circuit.

The current/voltage control circuit 23 generates various voltages according to an electric signal from the input circuit 22 and an electric signal from the protection circuit 24. In this embodiment, the current/voltage control circuit 23 includes a drive voltage generation circuit 30, a first constant voltage generation circuit 31, a second constant voltage generation circuit 32, and a reference voltage/reference current generation circuit 33.

The drive voltage generation circuit 30 generates a drive voltage for driving the gate control circuit 25. The drive voltage may be set to a value obtained by subtracting a predetermined value from the power supply voltage VB. The drive voltage generation circuit 30 may generate a drive voltage of 5 V or more and 15 V or less obtained by subtracting 5 V from the power supply voltage VB. The drive voltage is input to the gate control circuit 25.

The first constant voltage generation circuit 31 generates a first constant voltage for driving the protection circuit 24. The first constant voltage generation circuit 31 may include a Zener diode or a regulator circuit (here, the Zener diode). The first constant voltage may be 1 V or more and 5 V or less. The first constant voltage is input to the protection circuit 24 (more specifically, a load open detection circuit 35 or the like to be described later).

The second constant voltage generation circuit 32 generates a second constant voltage for driving the protection circuit 24. The second constant voltage generation circuit 32 may include a Zener diode or a regulator circuit (here, the regulator circuit). The second constant voltage may be 1 V or more and 5 V or less. The second constant voltage is input to the protection circuit 24 (more specifically, an overheat protection circuit 36 and a low voltage malfunction suppression circuit 37 to be described later).

The reference voltage/reference current generation circuit 33 generates a reference voltage and a reference current of various circuits. The reference voltage may be 1 V or more and 5 V or less. The reference current may be 1 mA or more and 1 A or less. The reference voltage and reference current are input to various circuits. In a case where the various circuits include a comparator, the reference voltage and reference current may be input to a comparator.

The protection circuit 24 is connected to the current/voltage control circuit 23, the gate control circuit 25, the abnormality detection circuit 29, the source of the power MISFET 9, and the source of the sensor MISFET 21. The protection circuit 24 includes an overcurrent protection circuit 34, a load open detection circuit 35, an overheat protection circuit 36, and a low voltage malfunction suppression circuit 37.

The overcurrent protection circuit 34 protects the power MISFET 9 from overcurrent. The overcurrent protection circuit 34 is connected to the gate control circuit 25 and the source of the sensor MISFET 21. The overcurrent protection circuit 34 may include a current monitor circuit. A signal generated by the overcurrent protection circuit 34 is input to the gate control circuit 25 (more specifically, a drive signal output circuit 40 to be described later).

The load open detection circuit 35 detects the short state and the open state of the power MISFET 9. The load open detection circuit 35 is connected to the current/voltage control circuit 23 and the source of the power MISFET 9. A signal generated by the load open detection circuit 35 is input to the current/voltage control circuit 23.

The overheat protection circuit 36 monitors the temperature of the power MISFET 9 and protects the power MISFET 9 from an excessive temperature rise. The overheat protection circuit 36 is connected to the current/voltage control circuit 23. The overheat protection circuit 36 may include a temperature sensitive device such as a temperature sensitive diode or a thermistor. A signal generated by the overheat protection circuit 36 is input to the current/voltage control circuit 23.

The low voltage malfunction suppression circuit 37 suppresses the malfunction of the power MISFET 9 when the power supply voltage VB is less than a predetermined value. The low voltage malfunction suppression circuit 37 is connected to the current/voltage control circuit 23. A signal generated by the low voltage malfunction suppression circuit 37 is input to the current/voltage control circuit 23.

The gate control circuit 25 controls on and off states of the power MISFET 9 and on and off states of the sensor MISFET 21. The gate control circuit 25 is connected to the current/voltage control circuit 23, the protection circuit 24, the gate of the power MISFET 9, and the gate of the sensor MISFET 21.

The gate control circuit 25 outputs a gate control signal VG to the gate control wiring 17 in response to an electric signal from the current/voltage control circuit 23 and an electric signal from the protection circuit 24. The gate control signal VG is input to each of the gate of the power MISFET 9 and the gate of the sensor MISFET 21 via the gate control wiring 17. Specifically, the gate control circuit 25 turns on/off the power MISFET 9 by controlling the gate control signal VG in response to an electric signal (input signal) applied to the input electrode 13.

More specifically, the gate control circuit 25 includes an oscillation circuit 38, a charge pump circuit 39, and a drive signal output circuit 40. The oscillation circuit 38 oscillates in response to the electric signal from the current/voltage control circuit 23 and generates a predetermined electric signal. The electric signal generated by the oscillation circuit 38 is input to the charge pump circuit 39. The charge pump circuit 39 generates a boosted voltage VCP based on the electric signal from the oscillation circuit 38. The boosted voltage VCP generated by the charge pump circuit 39 is input to the drive signal output circuit 40.

The drive signal output circuit 40 operates by receiving the boosted voltage VCP output from the charge pump circuit 39, and generates the gate control signal in response to the electric signal from the protection circuit 24 (more specifically, the overcurrent protection circuit 34). The gate control signal VG is input to the gate of the power MISFET 9 and the gate of the sensor MISFET 21 via the gate control wiring 17. The sensor MISFET 21 and the power MISFET 9 are simultaneously controlled by the gate control circuit 25.

The active clamp circuit 26 protects the power MISFET 9 from a counter electromotive force. The active clamp circuit 26 is connected to the drain electrode 11, the gate of the power MISFET 9, and the gate of the sensor MISFET 21. The active clamp circuit 26 may include a plurality of diodes.

The active clamp circuit 26 may include a plurality of diodes forward-bias-connected to one another. The active clamp circuit 26 may include a plurality of diodes reverse-bias-connected to one another. The active clamp circuit 26 may include a plurality of diodes forward-bias-connected to one another and a plurality of diodes reverse-bias-connected to one another.

The plurality of diodes may include a pn junction diode, a Zener diode, or a pn junction diode and a Zener diode. The active clamp circuit 26 may include a plurality of Zener diodes bias-connected to one another. The active clamp circuit 26 may include a Zener diode and a pn junction diode reverse-bias-connected to one another.

The current detection circuit 27 detects a current flowing through the power MISFET 9 and the sensor MISFET 21. The current detection circuit 27 is connected to the protection circuit 24, the abnormality detection circuit 29, the source of the power MISFET 9, and the source of the sensor MISFET 21. The current detection circuit 27 generates a current detection signal in response to the electric signal (the output current IOUT) generated by the power MISFET 9 and the electric signal (a sense current exhibiting the same behavior as the output current IOUT) generated by the sensor MISFET 21. The current detection signal is input to the abnormality detection circuit 29.

The power supply reverse connection protection circuit 28 protects the current/voltage control circuit 23, the power MISFET 9, and the like from a reverse voltage when the DC power supply 2 is connected in reverse. The power supply reverse connection protection circuit 28 is connected to the reference voltage electrode 14 and the current/voltage control circuit 23.

The abnormality detection circuit 29 monitors the voltage of the protection circuit 24. The abnormality detection circuit 29 is connected to the current/voltage control circuit 23, the protection circuit 24, and the current detection circuit 27. When an abnormality (voltage fluctuation, etc.) occurs in any of the overcurrent protection circuit 34, the load open detection circuit 35, the overheat protection circuit 36, and the low voltage malfunction suppression circuit 37, the abnormality detection circuit 29 generates an abnormality detection signal in response to the voltage of the protection circuit 24 and outputs the same to the outside.

More specifically, the abnormality detection circuit 29 includes a first multiplexer circuit 41 and a second multiplexer circuit 42. The first multiplexer circuit 41 includes two input parts, one output part, and one selective control input part. The protection circuit 24 and the current detection circuit 27 are connected to the input parts of the first multiplexer circuit 41, respectively. The second multiplexer circuit 42 is connected to the output part of the first multiplexer circuit 41. The current/voltage control circuit 23 is connected to the selective control input part of the first multiplexer circuit 41.

The first multiplexer circuit 41 generates an abnormality detection signal in response to the electric signal from the current/voltage control circuit 23, the voltage detection signal from the protection circuit 24, and the current detection signal from the current detection circuit 27. The abnormality detection signal generated by the first multiplexer circuit 41 is input to the second multiplexer circuit 42.

The second multiplexer circuit 42 includes two input parts and one output part. The output part of the second multiplexer circuit 42 and the enable electrode 15 are connected to the input parts of the second multiplexer circuit 42, respectively. The sense electrode 16 is connected to the output part of the second multiplexer circuit 42.

When an MCU is connected to the enable electrode 15 and a pull-up or pull-down resistor is connected to the sense electrode 16, an on signal is input from the MCU to the enable electrode 15 and an abnormality detection signal is output from the sense electrode 16. The abnormality detection signal is converted into an electric signal by a resistor connected to the sense electrode 16. The abnormality state of the semiconductor device 1 is detected based on this electric signal.

### <Consideration on Detection Accuracy of Overcurrent>

The semiconductor device 1 described above is an electronic circuit configured to control the power supply to the load and an intelligent protection function is mounted inside the device. For example, the output current IOUT which is supplied to the load 3 is limited to the upper limit or less by the overcurrent protection circuit 34.

By the way, as the number of electrical or electronic loads built into a vehicle increases, the need for in-vehicle IPD with lower on-resistance increases to reduce power consumption of the loads and improve efficiency of the vehicle as a whole. As a result, as nominal amperage of the load increases, so does the need to detect an overcurrent more accurately and apply more advanced overcurrent protection.

However, almost all overcurrent protection circuits that are monolithically mounted on a general in-vehicle IPD use a current limiting comparator. In the current limiting comparator, the upper limit value (limiting threshold) of the overcurrent is internally defined based on a voltage difference AVbe between a base and an emitter of a bipolar transistor or a voltage difference AVgs between the gate and the source of an MOS transistor. Therefore, the detection accuracy of the overcurrent may not be high (±30% or less).

In the following, an overcurrent protection circuit 34 capable of detecting and limiting the overcurrent with high accuracy according to a first embodiment of the present disclosure is proposed.

### <Overcurrent Protection Circuit (First Embodiment)>

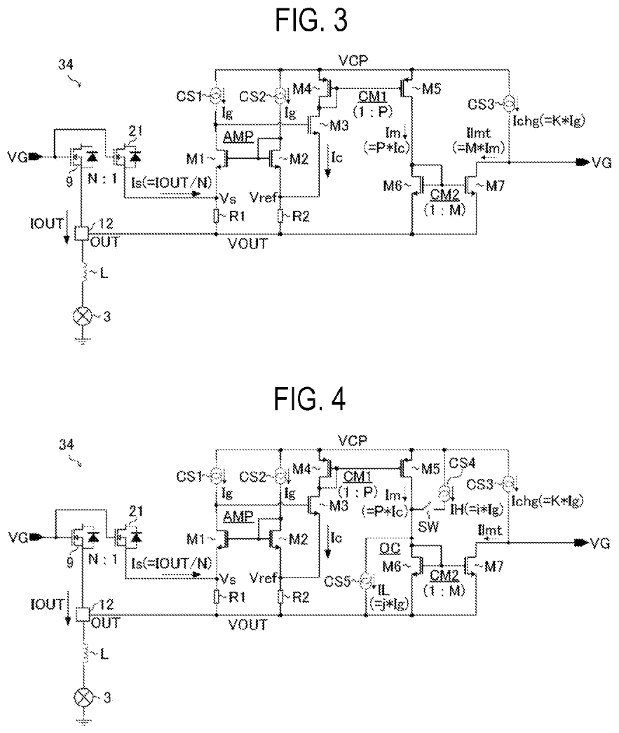

FIG. 3 is a diagram showing the overcurrent protection circuit 34 according to the first embodiment. The overcurrent protection circuit 34 according to the first embodiment is a kind of abnormality protection circuit in which the output current IOUT flowing through the power MISFET 9 (corresponding to the output transistor) is set as a monitoring target current and is limited to a predetermined upper limit or less, and includes transistors M1 to M7 (in this figure, the transistors M1 to M3, M6, and M7 are N-channel type MISFETs, and the transistors M4 and M5 are P-channel type MISFETs), current sources CS1 to CS3, and resistors R1 and R2.

The first end of each of the current sources CS1 and CS2 is connected to an application end of the boosted voltage VCP. The second end of the current source CS1 and the drain of the transistor M1 are connected to the gate of the transistor M3. The second end of the current source CS2 and the drain of the transistor M2 are connected to the gates of the transistors M1 and M2, respectively.

The source of the transistor M1 and the first end of the resistor R1 are connected to the source of the sensor MISFET 21. The first end of the resistor R1 corresponds to an application end of a detection signal Vs. The source of each of the transistors M2 and M3 is connected to the first end of the resistor R2. The first end of the resistor R2 corresponds to the application end of a reference signal Vref. The second end of each of the resistors R1 and R2 is connected to the application end (the source electrode 12) of the output voltage VOUT.

The source of each of the transistors M4 and M5 is connected to the application end of the boosted voltage VCP. The gate of each of the transistors M4 and M5 is connected to the drain of the transistor M4. The drain of the transistor M4 is connected to the drain of the transistor M3. The drain of the transistor M3 corresponds to the output end of a current output signal Ic.

The source of each of the transistors M6 and M7 is connected to the application end of the output voltage VOUT. The gate of each of the transistors M6 and M7 is connected to the drain of the transistor M6. The drain of the transistor M6 is connected to the drain of the transistor M5. The drain of the transistor M6 corresponds to the output end of a minor current

The first end of the current source CS3 is connected to the application end of the boosted voltage VCP. The second end of the current source CS3 and the drain of the transistor M7 are connected to the application end of the gate control signal VG (the gate of the power MISFET 9).

Among the above constituent elements, the transistors M1 and M2 correspond to a first transistor and a second transistor configured to form the input stage of a current output amplifier AMP together with the current sources CS1 and CS2. The current output amplifier AMP operates as a one-stage OTA (Operational Transconductance Amplifier) having an appropriate common mode input voltage range via a source connection input.

The transistor M1 receives the input of the detection signal Vs in response to the output current IOUT. As shown in this figure, the detection signal Vs (=(Is+Ig)xR1) corresponding to the sense current Is (=IOUT/N, where N>1) flowing through the sensor MISFET 21 is applied to the source of the transistor M1.

The transistor M2 generates a gate bias of the transistor M1 to appropriately compensate for a Vgs offset of the transistor M1. As shown in this figure, the reference signal Vref (=Ig×R2) is applied to the source of the transistor M2.

The transistor M3 corresponds to a third transistor configured to form the output stage of the current output amplifier AMP. As shown in this figure, the output stage of the current output amplifier AMP generates a current output signal Ic according to a difference between the detection signal Vs and the reference signal Vref, and causes the current output signal Ic to be negatively fed back to the input stage of the current output amplifier AMP. By providing such a negative feedback path, the matching of the transistors M1 and M2 forming the input stage of the current output amplifier AMP is improved.

The current output signal Ic starts to flow when the detection signal Vs becomes equal to the reference signal Vref, that is, when the following equation (1) is established.

{(IOUT/N)+Ig}*R1=Ig*R2 (1)

Further, the current output signal Ic flowing at this time is expressed by the following equation (2).

Ic=(IOUT/N)*(R1/R2)—Ig (2)

As can be seen from the above equation (2), the current output signal Ic includes detection information of the output current IOUT.

The current source CS1 corresponds to a first current source that is connected between the application end (corresponding to a first potential node) of the boosted voltage VCP and the drain of the transistor M1, and is configured to generate a predetermined reference current Ig.

The current source CS2 corresponds to a second current source that is connected between the application end of the boosted voltage VCP and the drain of the transistor M2, and is configured to generate a predetermined reference current Ig.

The resistance R1 corresponds to a first resistor configured to be connected between the source of the transistor M1 and the application end (corresponding to a second potential node) of the output voltage VOUT. The resistor R1 may also be understood as a sense resistor that converts the sense current Is (current signal) into the detection signal Vs (voltage signal).

The resistor R2 corresponds to a second resistor configured to be connected between the source of the transistor M2 and the application end of the output voltage VOUT.

The transistors M4 and M5 correspond to a current mirror CM1 that generates a mirror current Im (=P×Ic) by replicating the current output signal Ic, which is output from the drain of the transistor M3, with a predetermined mirror ratio P (where P≥1).

The transistors M6 and M7 correspond to a current mirror CM2 that generates a current limiting signal Ilmt (=M×Im) by replicating the mirror current Im, which is output from the drain of the transistor M5, with a predetermined mirror ratio M (where M≥1).

That is, the transistors M4 to M7 have roles of a current mirror and a current gain.

The current source CS3 corresponds to a third current source that is connected between the application end of the boost voltage VCP and the application end (the gate of the power MISFET 9) of the gate control signal VG, and is configured to generate a gate charge signal Ichg (=K×Ig, where K≥1) for turning on the power MISFET 9. The current source CS3 may also be understood as a constituent element of the gate control circuit 25, not as a constituent element of the overcurrent protection circuit 34.

The above-mentioned current limiting signal Ilmt is a current signal drawn from the application end of the gate control signal VG to the application end of the output voltage VOUT via the transistor M7. Therefore, when the current limiting signal Ilmt flows, the gate control signal VG is lowered. As a result, since the on-resistance of the power MISFET 9 is increased, the output current IOUT is limited.

In this way, the overcurrent protection circuit 34 according to the present embodiment limits the output current IOUT by controlling the gate control signal VG of the power MISFET 9 based on the current limiting signal Ilmt (and thus the current output signal Ic).

In particular, in the overcurrent protection circuit 34 according to the present embodiment, the input stage that receives the detection result of the output current IOUT operates not as a comparator but as an operational amplifier (more specifically, OTA). Therefore, the detection accuracy of the output current IOUT is improved as compared with a configuration using the comparator.

Further, since a local negative feedback path is established by using the transistor M3, matching of an input pair (the transistors M1 and M2) is improved, such that characteristics of the entire circuit are improved.

In the overcurrent protection circuit 34 according to the present embodiment, the limitation of the output current IOUT is achieved when the following equation (3) is established.

Ilmt=Ichg

⇔P*M*Ic=K*Ig

⇔IOUT={(K+M*P)/(M*P)}*N*(R2/R1)*Ig (3)

Here, the reference signal Vref (corresponding to a threshold value of the detection signal Vs at which the current output signal Ic starts to flow) used as a threshold value of overcurrent limit is generated by using the reference current Ig used to generate the gate charge signal Ichg. Therefore, it is possible to apply a highly-accurate output current limit.

Further, in the overcurrent protection circuit 34 according to the present embodiment, the MISFET is used as the transistors M1 and M2 forming the input stage of the current output amplifier AMP, but, for example, the transistors M1 and M2 may be replaced with bipolar transistors.

Further, the current output amplifier AMP is not limited to the one-stage OTA, but may employ other types of regulation operational amplifiers. Further, a topology for detecting and regulating the output current IOUT is not limited to the above-described circuit configuration.

### <Consideration on Inrush Current Control and Short-circuit Robustness>

Currently, some of general loads used in automobiles, etc., show capacitive operation (light bulbs, etc.). There are also loads that are specially designed to draw a large transient current (so-called inrush current) when a capacitive storage device (power supply, airbag, etc.) is first activated.

Such an inrush current needs to be handled correctly by an in-vehicle IPD, and care needs to be taken not to apply unnecessary overcurrent protection. Otherwise, a load may be hindered from being normally booted, or it may not be booted at all. For example, since a bulb lamp that may be connected as a load has thermal inertia, it needs to be warmed up before reaching a nominal current operation.

Further, for example, in an airbag system, a capacitive charge reservoir may draw a significant inrush current at start-up. Limiting such an inrush current as an abnormal overcurrent may lead to fatal malfunction in the operation of the airbag system.

However, the above-mentioned inrush current may exceed a maximum current capacity (for example, a maximum current capacity of a short-circuit event defined in AEC-Q100-012) of the in-vehicle IPD in the steady state. Therefore, the overcurrent protection circuit needs to appropriately limit an overcurrent when the overcurrent occurs in the steady state while allowing the inrush current that flows at the time of start-up (or when the device is active).

In view of the above considerations, an overcurrent protection circuit 34 capable of achieving both inrush current control and short-circuit robustness while detecting an overcurrent with high accuracy according to a second embodiment of the present disclosure is proposed below.

### <Overcurrent Protection Circuit (Second Embodiment)>

FIG. 4 is a diagram showing the overcurrent protection circuit 34 according to the second embodiment. The overcurrent protection circuit 34 according to the second embodiment is based on the first embodiment (FIG. 3) and further includes an offset control part OC. Therefore, the already-mentioned constituent elements are denoted by the same reference numerals as those in FIG. 3 and explanation thereof will be omitted, and the feature portions of the second embodiment will be mainly described below.

The offset control part OC is a circuit part that controls an offset signal (details of which will be described later) applied to the current limit signal Ilmt, and includes current sources CS4 and CS5 and a switch SW.

The current source CS4 corresponds to a fourth current source that is connected between the application end of the boosted voltage VCP and the drain of the transistor M5, and is configured to generate an upper offset current IH (=i×lg).

The current source CS4 corresponds to a fifth current source that is connected between the drain of the transistor M5 and the application end of the output voltage VOUT, and is configured to generate a lower offset current IL (=j×Ig).

The switch SW is connected in series with the current source CS4 between the application end of the boost voltage VCP and the transistor M5, and electrically connects/disconnects a current path of the upper offset current IH.

In the overcurrent protection circuit 34 according to the present embodiment, when the switch SW is off, the limitation of the output current IOUT is achieved when the following equation (4) is established.

Ilmt=Ichg

⇔M*(P*Ic−j*Ig)=K*Ig

⇔IOUT={(K+M*P+M*j)/(M*P)}*N*(R2/R1)*Ig (4)

Therefore, for example, when K=5 M, P=5, and j=14, the output current IOUT is limited so that the relationship of IOUT=(24/5)*N*(R2/R1)*Ig is established.

On the other hand, when the switch SW is on, the limitation of the output current IOUT is achieved when the following equation (5) is established.

Ilmt =Ichg

⇔M*(P*Ic+i*Ig−j*Ig)=K*Ig

⇔IOUT=[{K+M*P+M*(j−i)}/(M*P)]*N*(R2/R1)*Ig (5)

Therefore, for example, when K=5 M, P=5, i=12, and j=14, the output current IOUT is limited so that the relationship of IOUT=(12/5)*N*(R2/R1) is established.

That is, by controlling the on/off of the switch SW, the upper limit value of the output current IOUT may be arbitrarily changed without affecting the detection accuracy of the entire overcurrent protection circuit 34. Therefore, it is possible to achieve both inrush current control and short-circuit robustness while detecting the overcurrent with high accuracy.

For example, according to the above-described numerical value setting example, the upper limit value of the output current IOUT set when the switch SW is in the on state is reduced to ½ of the upper limit value of the output current IOUT set when the switch SW is in the off state.

Of course, the above-described numerical value setting example is merely an example, and the same effect may be obtained even in a case where other numerical values are set. Further, the upper offset current IH and the lower offset current IL are not limited to fixed values and may be, for example, variable values according to the elapsed time after the power is turned on or a voltage between the drain and the source of the power MISFET 9.

For example, the switch SW may be off for a predetermined fixed time (or an arbitrary variable time) after starting to supply the output current IOUT to the capacitive load 3, and then may be on. By performing such on/off control, for example, it is possible to both allow an inrush current when a bulb lamp is warmed up and limit an overcurrent in the steady state.

Further, the inrush current flowing through the capacitive load 3 is transient, and the time to allow this may be short (about several tens of ms after the power is turned on). Further, the upper limit value of the output current IOUT set when the switch SW is in the off state may be set to an appropriate value in consideration of the element withstand voltage of the power MISFET 9.

Further, without being limited to the timer control as described above, the on/off control of the switch SW may be performed according to the detection result of the drain-source voltage of the power MISFET 9. Specifically, the switch SW may be on when the drain-source voltage of the power MISFET 9 is higher than a predetermined threshold voltage. According to such on/off control, when a ground fault of the source electrode 12 is suspected, the upper limit value of the output current IOUT may be lowered. Therefore, since an excessive short-circuit current is appropriately limited, it is possible to improve the safety of the semiconductor device 1.

Further, with the overcurrent protection circuit 34 according to the present embodiment, it is possible to achieve both inrush current control and short-circuit robustness with a relatively simple and low-cost circuit configuration without requiring a complicated architecture of a memory circuit or the like.

### <Application to Vehicle>

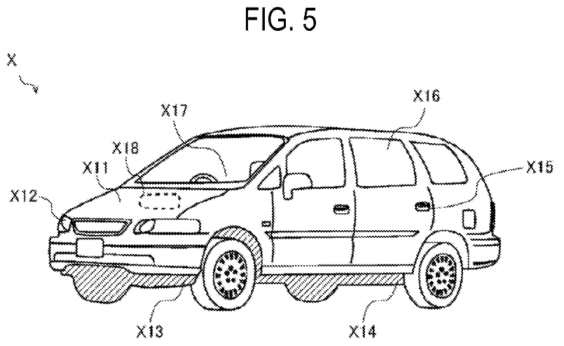

FIG. 5 is an external view showing a configuration example of a vehicle X. The vehicle X of this configuration example is equipped with a battery (not shown in this figure) and various electronic apparatuses X11 to X18 that operate by receiving electric power from the battery.

The vehicle X includes not only an engine vehicle but also an electric vehicle (xEV such as BEV [Battery Electric Vehicle], HEV [Hybrid Electric Vehicle], PHEV/PHV [Plug-in Hybrid Electric Vehicle/Plug-in Hybrid Vehicle], or FCEV/FCV [Fuel Cell Electric Vehicle/Fuel Cell Vehicle]).

The mounting positions of the electronic apparatuses X11 to X18 in this figure may differ from actual ones for convenience of illustration.

The electronic apparatus X11 is an electronic control unit that performs engine-related control (injection control, electronic throttle control, idling control, oxygen sensor heater control, auto-cruise control, etc.) or motor-related control (torque control, power regeneration control, etc.).

The electronic apparatus X12 is a lamp control unit that performs lighting-on/off control of HID [High Intensity Discharged Lamp], DRL [Daytime Running Lamp], etc.

The electronic apparatus X13 is a transmission control unit that performs transmission-related control.

The electronic apparatus X14 is a braking unit that performs control related to the motion of the vehicle X (ABS [Anti-lock Brake System] control, EPS [Electric Power Steering] control, electronic suspension control, etc.).

The electronic apparatus X15 is a security control unit that performs drive control of a door lock, a security alarm, etc.

The electronic apparatus X16 is an electronic apparatus incorporated in the vehicle X at a factory shipment stage, as standard equipment or manufacturer's options such as a wiper, an electric door mirror, a power window, a damper (shock absorber), an electric sunroof, an electric seat, etc.

The electronic apparatus X17 is an electronic apparatus that is optionally mounted on the vehicle X, as user's options such as an in-vehicle A/V [Audio/Visual] apparatus, a car navigation system, an ETC [Electronic Toll Collection] system, etc.

The electronic apparatus X18 is an electronic apparatus equipped with a high withstand voltage motor such as an in-vehicle blower, an oil pump, a water pump, a battery cooling fan, etc.

The above-described electronic apparatus A may be understood as the electronic apparatuses X11 to X18. That is, the above-described semiconductor device 1 may be incorporated into any of the electronic apparatuses X11 to X18.

### <Summary>

In the following, the above-described various embodiments will be comprehensively described.

For example, an overcurrent protection circuit disclosed in the present disclosure is configured to include: a first transistor and a second transistor configured to form an amplifier input stage that receives input of a detection signal according to a monitoring target current; and a third transistor configured to form an amplifier output stage that generates a current output signal according to a difference between the detection signal and a reference signal and causes the current output signal to be negatively fed back to the amplifier input stage, wherein the monitoring target current is limited based on the current output signal output from the third transistor (first configuration).

The overcurrent protection circuit of first configuration may be configured such that a first main electrode of the first transistor is connected to a control electrode of the third transistor, a first main electrode of the second transistor is connected to a control electrode of each of the first transistor and the second transistor, a first main electrode of the third transistor is connected to an output node of the current output signal, a second main electrode of the first transistor is connected to an application end of the detection signal, and a second main electrode of the second transistor is connected to a second main electrode of the third transistor (second configuration).

The overcurrent protection circuit of second configuration may be configured such that it further includes: a first current source configured to be connected between a first potential node and the first main electrode of the first transistor to generate a reference current; and a second current source configured to be connected between the first potential node and the first main electrode of the second transistor to generate the reference current (third configuration).

The overcurrent protection circuit of second or third configuration may be configured such that it further includes: a first resistance configured to be connected between the second main electrode of the first transistor and a second potential node; and a second resistance configured to be connected between the second main electrode of the second transistor and the second potential node (fourth configuration).

The overcurrent protection circuit of any one of first to fourth configurations may be configured such that it further includes: a current mirror configured to generate a current limiting signal by replicating the current output signal (fifth configuration).

The overcurrent protection circuit of fifth configuration may be configured such that it further includes: an offset controller configured to control an offset signal applied to the current limiting signal (sixth configuration).

Further, for example, a semiconductor device disclosed in the present disclosure is configured to include: an output transistor; and the overcurrent protection circuit of any one of first to sixth configurations, which is configured to set an output current flowing through the output transistor as the monitoring target current (seventh configuration).

The semiconductor device of seventh configuration may be configured such that the overcurrent protection circuit limits the output current by controlling a drive signal of the output transistor based on the current output signal (eight configuration).

Further, for example, an electronic apparatus disclosed in the present disclosure is configured to include the semiconductor device of seventh or eighth configuration (ninth configuration).

Further, for example, a vehicle disclosed in the present disclosure is configured to include the electronic apparatus of ninth configuration (tenth configuration).

### <Other Modifications>

In addition to the above-described embodiments, various technical features disclosed in the present disclosure may be modified in various ways without departing from the spirit of the technical creation. For example, mutual replacement between a bipolar transistor and a MOS field effect transistor or logic level inversion of various signals is optional. That is, it should be considered that the above-described embodiments are exemplary and are not restrictive in all respects, and the technical scope of the present disclosure is defined by the claims and should be understood to include all changes belonging within the meaning and scope equivalent to the claims.

According to the present disclosure in some embodiments, it is possible to provide a high-precision overcurrent protection circuit and a semiconductor device, an electronic apparatus, and a vehicle using the overcurrent protection circuit.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An overcurrent protection circuit comprising:
a first transistor and a second transistor configured to form an amplifier input stage that receives input of a detection signal according to a monitoring target current; and
a third transistor configured to form an amplifier output stage that generates a current output signal according to a difference between the detection signal and a reference signal and causes the current output signal to be negatively fed back to the amplifier input stage,
wherein the monitoring target current is limited based on the current output signal output from the third transistor.

2. The overcurrent protection circuit of claim 1, wherein a first main electrode of the first transistor is connected to a control electrode of the third transistor,
wherein a first main electrode of the second transistor is connected to a control electrode of each of the first transistor and the second transistor,
wherein a first main electrode of the third transistor is connected to an output node of the current output signal,
wherein a second main electrode of the first transistor is connected to an application end of the detection signal, and
wherein a second main electrode of the second transistor is connected to a second main electrode of the third transistor.

3. The overcurrent protection circuit of claim 2, further comprising:
a first current source configured to be connected between a first potential node and the first main electrode of the first transistor to generate a reference current; and
a second current source configured to be connected between the first potential node and the first main electrode of the second transistor to generate the reference current.

4. The overcurrent protection circuit of claim 2, further comprising:
a first resistance configured to be connected between the second main electrode of the first transistor and a second potential node; and
a second resistance configured to be connected between the second main electrode of the second transistor and the second potential node.

5. The overcurrent protection circuit of claim 1, further comprising a current mirror configured to generate a current limiting signal by replicating the current output signal.

6. The overcurrent protection circuit of claim 5, further comprising an offset controller configured to control an offset signal applied to the current limiting signal.

7. A semiconductor device comprising:
an output transistor; and
the overcurrent protection circuit of claim 1, which is configured to set an output current flowing through the output transistor as the monitoring target current.

8. The semiconductor device of claim 7, wherein the overcurrent protection circuit limits the output current by controlling a drive signal of the output transistor based on the current output signal.

9. An electronic apparatus comprising the semiconductor device of claim 7.

10. A vehicle comprising the electronic apparatus of claim 9.
